(19) United States
(12) Patent Application Publication
(10) Pub. No.: US 2024/0145615 A1
(43) Pub. Date: May 2, 2024

(54) SENSOR DEVICE

(71) Applicant: ams-OSRAM International GmbH, Regensburg (DE)

(72) Inventors: Tim BOESCKE, Regensburg (DE); Maximilian ASSIG, Regensburg (DE); Thomas SCHWARZ, Regensburg (DE); Andreas WALDSCHIK, Wolmirstedt (DE)

(21) Appl. No.: 18/278,221

(22) PCT Filed: Feb. 22, 2022
(86) PCT No.: PCT/EP2022/054433

§ 371 Date: Aug. 22, 2023

(30) Foreign Application Priority Data
Feb. 22, 2021 (DE) 10 2021 104 189.9

(51) Int. Cl. H01L 31/173; H01L 31/02; H01L 31/0203; H01L 31/0216

(52) U.S. Cl. CPC H01L 31/173; H01L 31/02005; H01L 31/0203; H01L 31/02164

(57) ABSTRACT

A sensor device includes a carrier having a via for guiding an electrical contact from a bottom surface to a top surface of the carrier. The device also includes an integrated circuit on the carrier, a sensor element, an optoelectronic component on the top surface of the carrier, and a first electrically conductive contact element on the via an electrically connected thereto. The device further includes a substantially opaque encapsulation material enclosing the sensor element, the optoelectronic component, and the first electrically conductive contact element such that a surface of the sensor element and of the optoelectronic component opposite the carrier is uncovered by the encapsulation material. The device additionally includes a first conductor track on the encapsulation material electrically connecting the first electrically conductive contact element and the integrated circuit, and a second conductor track on the encapsulation material electrically connecting the integrated circuit with the optoelectronic component.

The present application claims priority to German patent application No. 10 2021 104 189.9 of Feb. 22, 2021, the disclo-sure content of which is hereby incorporated by reference into the present application.

The present invention relates to a sensor device, in particular a sensor device for use in mobile devices such as smartphones, smartwatches, wearables (for example, fitness bracelets) and wireless headphones.

Due to the use of the sensor device in, for example, mobile end devices, it can be advantageous that it is particularly small, in particular thin, and light.

At present, emitter and detector chips with a thickness greater than or equal to 0.6 mm are known for use in a sensor device. In addition, fully integrated sensor devices (housing comprising an emitter, detector and integrated circuit (IC)) are known (e.g. AS7038RB SpO2 sensor from ams AG), which have a total thickness of greater than or equal to 0.65 mm.

However, it may be desired to provide a sensor device having a thickness less than the above dimensions.

Furthermore, it may be desired that in the case of sensor devices, in particular optical distance sensors, light emitted from an emitter of the device does not reach a detector of the device by a direct path and is detected by the latter.

In the case that the light emitted by the sensor device never-theless reaches the detector of the device on a direct path and is detected by it, one speaks of a so-called cross-talk of the sensor device. The signal detected by the detector due to the cross-talk adds up to a measurement signal detected by the detector and falsifies the measurement result.

Although it is possible to subtract a base amount (bias) from the detected signal and thus divide the detected signal into a cross-talk component and the actual measurement signal, such a procedure reduces the measurement accuracy of the sensor device, since the base amount to be subtracted can often only be deter-mined with insufficient accuracy.

At present, discrete partitions or openings are provided between the emitter and the detector to suppress optical crosstalk of a sensor device, for example. However, this may incur additional costs and, in particular, require additional installation space.

Another possibility is to arrange a reflective frame, in particular a white frame, around the emitter, which is intended to reflect the light emitted from the emitter to the side. In the case of a white material, however, a considerable part of the light is usually transmitted through the frame. An additional black material could provide a remedy, but this may be undesir-able for reasons of efficiency of the sensor device, in particular of the emitter.

Accordingly, it is an object of the present invention to provide a sensor device in which at least some of the above problematic aspects are addressed.

### SUMMARY OF THE INVENTION

The object is solved by a sensor device having the features of independent claim 1, a sensor device having the features of independent claim 17, and a sensor device having the features of independent claim 23. Embodiments and further embodiments of the invention are described in the dependent claims.

A sensor device according to the invention, in particular a sensor device for use in mobile devices such as smartphones, smartwatches, wearables (e.g. fitness bracelets) and wireless headphones, comprises a carrier substrate, in particular a printed circuit board, with at least one contact via for guiding an electrical contact from a bottom surface to a top surface of the carrier substrate. Furthermore, the sensor device comprises an integrated circuit arranged on the top surface of the carrier substrate, at least one sensor element arranged on or integrated into the integrated circuit and at least one light-emitting element or optoelectronic component arranged on the top surface of the carrier substrate at a distance from the integrated circuit. At least one first electrically conductive contact element is arranged on the at least one contact via and is electrically connected thereto, and a substantially opaque first encapsulation material encloses the at least one sensor element, the at least one light-emitting element, and the at least one first electrically conductive contact element in lateral direction such that at least one surface of the at least one sensor element and the at least one light-emitting element opposite the carrier substrate remains uncovered by the substantially opaque first encapsulation material. Furthermore, at least one first conductor track is formed on the substantially opaque first encapsulation material, which electrically connects the at least one first electrically conductive contact element and the integrated circuit to each other.

With the formulation “substantially opaque” it is understood in particular that no light or no light in the visible and/or infrared range or only a very small light component can pass through the corresponding material or object. In particular, the formulation “substantially opaque” can be understood in such a way that less than 1% of the light incident on the material or object, in particular in the visible and/or infrared range, transmits through the corresponding material or object.

By contrast, the formulation “at least partially transparent” is understood to mean that light in the visible and/or infrared range is transmitted through the corresponding material or object at least partially or largely unrestrictedly. In particular, the phrase “at least partially transparent” can be understood to mean that at least 70%, or more than 95%, of the light incident on the material or object, in particular in the visible and/or infrared range, is transmitted through the material or object.

By arranging the light emitting element or optoelectronic component in such a way that it is arranged at a distance from the integrated circuit on the top surface of the carrier substrate or is sensor element, and, by arranging the substantially opaque first encapsulation material such that at least one surface of the sensor element and the optoelectronic component opposite the carrier substrate remains uncovered by the substantially opaque first encapsulation material, crosstalk of the sensor device is reduced. Furthermore, the arrangement of the sensor element on or integrated into the integrated circuit, of the electrically conductive contact element on the at least one contact via and of the conductor track on the substantially opaque first encapsulation material for electrically contacting the electrically conductive contact element and the integrated circuit provides a particularly compact and, in particular, flat sensor device.

A structured layer of an substantially opaque material can additionally be arranged on the substantially opaque first encapsulation material. The layer is arranged in particular in such a way that the photosensitive region of the at least one sensor element and the light-emitting region of the at least one optoelectronic component remain uncovered by the substantially opaque material. Due to the structured layer, and due to the fact that the photosensitive region of the sensor element and the light-emitting region of the optoelectronic component remain uncovered, a frame is formed around the photosensitive region of the sensor element and the light-emitting region of the optoelectronic component, so to speak, so that a crosstalk of the sensor device can be reduced.

For this purpose, the structured layer of the substantially opaque material may comprise a photostructurable lacquer, in particular a black photostructurable epoxy or acrylic lacquer. Structuring of the layer may be accomplished using a photoli-thography process.

In some embodiments, the photosensitive region of the at least one sensor element and the light-emitting region of the at least one optoelectronic device remain completely uncovered. Accordingly, there is no material on the photosensitive region of the at least one sensor element and the light-emitting region of the at least one optoelectronic component, but the two areas are in contact with the surrounding atmosphere. This can be particularly advantageous, since it results in a desired refractive index jump both between the photosensitive region and the surrounding atmosphere, and between the light-emitting region and the surrounding atmosphere. Furthermore, in the case that the structured layer is arranged on the substantially opaque first encapsulation material, a refractive index jump results between the structured layer and the surrounding atmosphere, in particular at the side surfaces of the structured layer which are formed adjacent to the photosensitive region and the light-emitting region. This may, for example, increase the reflectivity of the side surfaces and reduce crosstalk of the sensing device.

In some embodiments, the photosensitive region of the at least one sensor element and the light-emitting region of the at least one optoelectronic device are covered by an at least partially transparent material. This makes it possible, for example, to ensure that the photosensitive region of the at least one sensor element and the light-emitting region of the at least one optoelectronic component are not damaged by external influences. For example, mechanical damage or damage caused by noxious gas can thus be prevented.

The carrier substrate can be formed in particular by a printed circuit board (PCB) and serves as a carrier for the electronic components. The PCB can be used in particular for mechanical fastening and for electrical connection of the electronic components. The printed circuit board can, for example, consist of an electrically insulating material with conductive connections (tracks) adhering to it. For example, fiber-reinforced plastic can be used as the insulating material. The printed circuit board can be characterized in particular by the fact that it has a low height or thickness. The height or thickness of the printed circuit board can, for example, be less than 350 μm, less than 250 μm or less than 200 μm.

The carrier substrate can also be formed by, for example, a lead frame or by a substrate which comprises the material ceramic, or consists of this at least in part. For example, the carrier substrate can be formed by a ceramic substrate.

A contact via can be understood in particular as a vertical electrical connection between the top surface and the bottom surface, i.e. the conductor track levels, of a printed circuit board. The connection can be realized, for example, by an in-ternally metallized hole in the carrier material of the printed circuit board, or by vertical etching through the printed circuit board and deposition of a metal in the structured areas of the non-conductor layers.

An integrated circuit (IC) may be disposed on the top surface of the carrier substrate. An integrated circuit can be formed, for example, by a wafer of semiconductor material on which an electronic circuit for controlling the sensor device, for operating the optoelectronic component, and/or for processing the measurement data is applied. The integrated circuit can be characterized in particular by the fact that it has particularly small dimensions, especially a small height/thickness. The height or thickness of the integrated circuit can, for example, be less than 250 μm, less than 150 μm or less than 100 μm.

The integrated circuit can, for example, be glued to the carrier substrate by means of an adhesive. For example, the integrated circuit may be bonded to an electrically conductive contact pad of the carrier substrate by means of an electrically conductive adhesive. Alternatively, the integrated circuit may be bonded or soldered to an electrically conductive contact pad on the carrier substrate. The connection between the integrated circuit and the carrier substrate may be characterized by the integrated circuit thereby being fixed to the top surface of the carrier substrate and optionally having electrically conductive properties. Furthermore, the connection between the integrated circuit and the carrier substrate may be characterized by having particularly small dimensions, in particular a small height or thickness. The height or thickness of the connection can be, for example, less than 20 μm, less than 15 μm or less than 10 μm.

The at least one sensor element is formed, for example, by a detector, in particular by a photodetector. Furthermore, the sensor element can also be formed by an array of several photodetectors or a photodetector with several differently photosensitive regions. In particular, the sensor element may be formed by a photodiode in the form of an unpackaged chip (“die”, “platelet” or bare chip, “bare chip”). Such an unhoused chip may be characterized in particular by having particularly small dimensions, in particular a small height/thickness. The height or thickness of the at least one sensor element can, for example, be less than 250 μm, less than 150 μm or less than 100 μm.

In particular, the sensor element can be designed in such a way that it can detect at least light of a wavelength that corre-sponds to the wavelength of the light emitted by the at least one optoelectronic component. Furthermore, the sensor element can be designed in such a way that it can detect several different wavelength ranges. For this purpose, different wavelength filters can be applied to areas of the sensor element, in particular to several photodetectors, for example, or the sensor element can consist of a matrix of detectors that can detect different wavelength ranges.

The at least one sensor element may be located on, or integrated into, the integrated circuit. In the case that the sensor element is integrated into the integrated circuit, a portion of a top surface of the integrated circuit may be formed by the photosensitive region of the sensing element. Consequently, the photosensitive region may be substantially planar with a top surface of the integrated circuit. For example, the photosensitive region may be disposed in an edge region of the top surface of the integrated circuit and may be formed by a portion of the top surface of the integrated circuit. In this case, electrical contacting and electrical control of the sensor element can be performed by the contact lines present in the integrated circuit and the semiconductor components present in the integrated circuit.

In the case that the sensor element is arranged on the integrated circuit, the sensor element and the integrated circuit can be formed by two separate components. For example, the sensor element may be arranged, in particular glued, on an edge region of the top surface of the integrated circuit. For example, the sensor element can be bonded to an electrically conductive contact pad of the integrated circuit by means of an electrically conductive adhesive. Further, the sensor element may be bonded, or soldered, to an electrically conductive contact pad of the integrated circuit. The connection between the integrated circuit and the carrier substrate may be characterized in that the sense element is thereby fixed to the top surface of the integrated circuit and optionally has electrically conductive properties. Furthermore, the connection between the sensor element and the integrated circuit may be characterized by having particularly small dimensions, in particular a small height or thickness. For example, the height or thickness of the connection can be less than 20 μm, less than 15 μm or less than 10 μm.

Electrical contact between the sensor element and the integrated circuit can be made alternatively or additionally via separate contact lines. The sensor element can be electrically controlled by the integrated circuit.

The at least one light-emitting element or opto-electronic component is formed, for example, by an infrared light-emitting surface emitter or VCSEL (vertical cavity surface-emitting laser), or an infrared light-emitting LED. By VCSEL can be meant in particular a laser diode in which the light is emitted per-pendicular to the plane of the semiconductor chip. However, it is also possible that the optoelectronic component emits light in the red, green, blue, or other wavelength range. The optoelectronic device may further be formed by an array of multiple optoelectronic devices, each emitting light of a different wavelength. For example, the optoelectronic device may be formed by three optoelectronic devices that emit light in red, green, and blue, thus forming an RGB pixel.

In some embodiments, the optoelectronic device is formed by a Flip chip. A Flip chip can be characterized, for example, by the fact that the connection contacts for operating the optoelectronic component are located on one side of the optoelectronic component. By arranging the connection contacts on one side of the optoelectronic device, for example, the overall height of the optoelectronic device may be reduced.

In some embodiments, the optoelectronic device is formed by a light emitting diode chip in the form of an unhoused chip (“die”, “platelet” or bare chip, “bare chip”). Such an unhoused chip can be characterized in particular by the fact that it has especially small dimensions, in particular a small height/thick-ness. For example, the height or thickness of the optoelectronic component may be less than 250 μm, less than 150 μm or less than 100 μm.

In some embodiments, at least one second conductor track is formed on the substantially opaque first encapsulation material to electrically interconnect the integrated circuit with the at least one optoelectronic device. The at least one second con-ductor track can be used, for example, for electrical contacting of the at least one optoelectronic component and/or for elec-trical control of the sensor element.

Both the first and the second conductor track can be formed, for example, by flat conductor tracks, in particular flat copper lines. The conductor tracks can be characterized in particular by the fact that they have particularly small dimensions, in particular a small height or a small thickness. For example, the height or thickness of the conductive traces may be less than 25 μm, less than 20 μm, or less than 15 μm.

In some embodiments, the sensor device does not exceed a total height of 400 μm. In particular, the sensor device may have an overall height of less than or equal to 360 μm. Such a compact design can be achieved in particular because the carrier sub-strate has contact vias on which an electrically conductive contact element is arranged. Furthermore, the sensor element is integrated in the integrated circuit, for example, and the integrated circuit and the electrically conductive contact element are connected to each other via flat conductor tracks. This allows space-saving electrical connection contacts to be pro-vided on the bottom surface of the carrier substrate.

In some embodiments, the at least one sensor element is disposed on the integrated circuit. In this case, the substantially opaque first encapsulation material is substantially flush with a surface of the at least one optoelectronic device and the integrated circuit opposite the carrier substrate. In particular, the substantially opaque first encapsulation material forms a first potting layer in which the at least one optoelectronic component, the integrated circuit, and the at least one first electrically conductive contact element are embedded. A surface of the at least one optoelectronic component opposite the car-rier substrate and of the integrated circuit lie in the same plane as a surface of the substantially opaque first encapsu-lation material opposite the carrier substrate. Only contact pads of the at least one optoelectronic component and of the integrated circuit as well as an edge region of the at least one first electrically conductive contact element may, for ex-ample, protrude beyond the substantially opaque first encapsu-lation material.

In some embodiments, at least one second electrically conductive contact element is disposed on the integrated circuit, partic-ularly on a contact pad of the integrated circuit. The at least one second electrically conductive contact element and the at least one sensor element disposed on the integrated circuit may further be laterally enclosed by a substantially opaque second encapsulation material. However, the substantially opaque sec-ond encapsulation material does not cover the light emitting region of the at least one optoelectric device and a surface of the at least one sensor element opposite the carrier substrate.

Rather, the substantially opaque second encapsulation material may have a window or cavity over the at least one optoelectronic device such that the substantially opaque second encapsulation material is recessed over the at least one optoelectronic de-vice.

In particular, the substantially opaque second encapsulation material forms a second potting layer in which the at least one sensor element, and the at least one second electrically conductive contact element are embedded. A surface of the at least one sensor element opposite the carrier substrate lies in particular in the same plane as a surface of the substantially opaque second encapsulation material opposite the carrier sub-strate. Only contact pads of the at least one sensor element, as well as an edge region of the at least one second electrically conductive contact element can, for example, protrude beyond the substantially opaque second encapsulation material.

In some embodiments, the window or cavity over the at least one optoelectronic device is filled with an at least partially transparent material, for example glass, or a glass chip.

In some embodiments, at least one third conductor track is formed on the substantially opaque second encapsulation mate-rial. In particular, the at least one third conductor track is formed such that it electrically connects the at least one sensor element to the at least one second electrically conduc-tive contact element.

The at least one third conductor track can also be formed, for example, by a flat conductor track, in particular a flat copper conductor track. The conductor track can be characterized in particular by the fact that it has particularly small dimen-sions, in particular a small height or a small thickness. For example, the height or thickness of the conductive track may be less than 25 μm, less than 20 μm or less than 15 μm.

In some embodiments, at least one of the at least one first, the at least one second and the at least one third conductor track is formed by a planar interconnect. A planar interconnect is characterized in particular by its planar or flat contacting of electronic components, for example semiconductor components. Conventionally used bonding wires can be replaced by a planar interconnect in the form of a thin, flat metal connector, whereby the semiconductor component is moved to the surface of the package and no additional encapsulation is required to pro-tect the bonding wire. For example, a planar interconnect may be fabricated similarly to a redistribution layer (RDL) and formed accordingly.

In some embodiments, at least one of the at least one first and the at least one second electrically conductive contact elements is formed by a metallic ellipsoid. For example, the metallic ellipsoid is formed by a metallic sphere or by an at least partially metallic sphere. For example, the metallic ellipsoid may be made of copper or at least comprise the material copper. Further, the metallic ellipsoid may comprise or at least com-prise a solder connection. In particular, the metallic ellipsoid may comprise a copper core coated with a material particularly suitable for a solder connection. For example, the metallic ellipsoid may be formed by a Cu-ball, Cu-core-ball or solder-ball. The metallic ellipsoid may be formed by a body that only approximates an ellipsoid. In some embodiments, this may be a half-ellipsoid. The metallic ellipsoid can be characterized in particular by the fact that it has particularly small dimen-sions, in particular a small diameter or a small height. For example, the diameter or height of the metallic ellipsoid may be smaller than 250 μm, smaller than 150 μm or smaller than 100 μm.

In some embodiments, the metallic ellipsoid is disposed on and electrically connected to the at least one contact via. In particular, the metallic ellipsoid is electrically connected to the contact via by means of a solder connection such as, for example, a tin-silver-copper solder connection (SAC from nar-rowly Sn—Ag—Cu).

In some embodiments, wherein at least one of the at least one first and the at least one second electrically conductive contact element is formed by at least two stud bumps stacked on top of each other or by at least two nailheads produced by a ball bonding process. So-called “stud bump pillars” can be formed by stacking the stud bumps or nailheads produced by a ball bonding process. The stud bumps or nailheads can be pro-duced by a nailhead-wirebond process or ballbonding process, in which a nailhead or ball is produced on the carrier substrate with a wire bonder and the wire running from the wire bonder is torn off directly above the nailhead or ball to produce the nailhead or ball. This creates a so-called “stud bump” or “nail-head”. Several such stud bumps or nailheads can be stacked or arranged to form a pillar. The wire for the nailhead wirebonding process or ballbonding process may be, for example, a gold wire, a copper wire, an aluminum wire, or an alloy wire comprising at least one of the latter materials.

In some embodiments, at least one of the at least one first and at least one second electrically conductive contact elements is formed by an opening through the substantially opaque first encapsulation material. The side surfaces of the opening are thereby metallized to provide the electrically conductive prop-erties. In particular, the metallization of the side surfaces of the opening may be provided by means of the corresponding first, second or third conductor track disposed on the electrically conductive contact element. The opening, or via hole, may be created, for example, by a laser ablation process in the substantially opaque first encapsulation material. When apply-ing the first, second or third conductor track to the electrically conductive contact element, the side surfaces of the open-ing may be simultaneously covered using the same material as the conductor track and thereby metallized.

In some embodiments, an insulation layer is formed between the at least one first conductor track and a partial region, in particular edge region, of the integrated circuit. The insula-tion layer is arranged on the partial area of the integrated circuit in such a way that the at least one first conductor track makes electrical contact with a contact pad of the integrated circuit, but is electrically insulated from a surface of the integrated circuit opposite the carrier substrate.

In some embodiments, an insulation layer is formed between the at least one second conductor track and a partial region, in particular edge region, of the integrated circuit and/or between the at least one second conductor track and a partial region, in particular edge region, of the light-emitting element. The insulation layer is arranged on the partial region of the integrated circuit in such a way that the at least one second conductor track makes electrical contact with a contact pad of the integrated circuit, but is electrically insulated from a surface of the integrated circuit opposite the carrier sub-strate, and/or the insulation layer is arranged on the partial region of the light-emitting element in such a way that the at least one second conductor track is electrically insulated from a surface of the integrated circuit opposite the carrier sub-strate, that the at least one second conductor track electrically contacts a contact pad of the light emitting element, but is electrically insulated from a surface of the light emitting element opposite the carrier substrate.

In some embodiments, an insulation layer is formed between the at least one third conductor track and a partial region, in particular edge region, of the sensor element. In this case, the insulation layer is arranged on the partial region of the sensor element in such a way that the at least one third con-ductor track makes electrical contact with a contact pad of the sensor element, but is electrically insulated from a surface of the sensor element opposite the carrier substrate.

In some embodiments, an at least partially transparent encapsulation material is disposed on the substantially opaque first encapsulation material or on the substantially opaque second encapsulation material. The at least partially transparent en-capsulation material thereby covers at least the at least one sensor element. However, the at least partially transparent encapsulation material may also cover the at least one optoelectronic component and/or the integrated circuit and/or at least one of the electrically conductive contact elements and conductor tracks.

In some embodiments, the substantially opaque first encapsula-tion material has an elevation, in particular a dam, in an area between the at least one sensor element and the at least one optoelectronic device. The elevation is designed in particular in such a way that it projects beyond the at least one optoelectronic component and/or the at least one sensor element and thus acts as a partition or diaphragm between the sensor element and the optoelectronic component. In particular, the protrusion can be designed in such a way that light emitted by the optoelectronic component does not reach the sensor element directly. In this way, in particular, a crosstalk of the sensor device can be reduced.

The elevation can, for example, take place in the same process step as an application of the substantially opaque first encapsulation material to the carrier substrate, or can be applied in a further step to an already existing layer of the substan-tially opaque first encapsulation material.

To increase the reflectivity of the elevation, the at least one second conductor track can run on the elevation, so that a crosstalk of the sensor device can be reduced.

Individual aspects and features of the preceding embodiments and examples may be readily combined without affecting the prin-ciple of the invention. Further, aspects and features of the preceding embodiments and examples may be combined with the further sensor device now described without thereby compromis-ing the principle of the invention. This includes, among other things, the type and design of the at least one contact via through the carrier substrate, the type and design of the integrated circuit or of the at least one sensor element and of the at least one optoelectronic component, and the type and design of the conductor tracks.

A further sensor device according to the invention comprises a carrier substrate, in particular a printed circuit board, a lead frame, or a ceramic substrate, having at least one contact via for guiding an electrical contact from a bottom surface to a top surface of the carrier substrate. Further, the carrier sub-strate has at least a first cavity in which an integrated circuit is disposed. At least one sensor element is arranged on the integrated circuit or is integrated therein. By means of a first conductor track formed on the carrier substrate, the at least one contact via and the integrated circuit are electrically connected to each other. An at least partially transparent encapsulation material covers at least the integrated circuit and the first electrical trace.

In some embodiments, the carrier substrate comprises at least a second cavity in which an optoelectronic device is arranged. In particular, the second cavity is formed adjacent to the first cavity, but is not connected to the first cavity. Accordingly, a web formed by the carrier substrate extends between the two cavities.

By arranging the integrated circuit or the sensor element in a first cavity of the printed circuit board and by arranging an optoelectronic component in a second cavity of the printed circuit board, a crosstalk of the sensor device can be reduced. The side surfaces of the cavities or the web between the two cavities acts as a partition or diaphragm between the sensor element and the optoelectronic device, so that a direct path of light emitted from the optoelectronic device to the sensor element is interrupted.

For this purpose, the first or the second cavity can be formed in such a way that a top surface of the integrated circuit or the photosensitive region of the sensor element and the light-emitting region of the optoelectronic component do not protrude beyond the carrier substrate.

The first and the second cavity, respectively, can be formed in such a way that they have at least the same size as the integrated circuit or the optoelectronic component, respectively, when viewed from above on the carrier substrate. In some embod-iments, only a small gap may be formed between the side surfaces of the cavities and the integrated circuit or optoelectronic device. In particular, the gap has a width of less than or equal to 100 μm, less than or equal to 50 μm, or less than or equal to 30 μm.

In some embodiments, the carrier substrate has at least one further contact via and a second conductor track, wherein the second conductor track is formed on the carrier substrate and electrically connects the at least one further contact via and the optoelectronic device.

Both the first and the second conductor tracks can be formed, for example, by flat conductor tracks, in particular flat copper lines. The conductor tracks can be characterized in particular by the fact that they have particularly small dimensions, in particular a small height or a small thickness. In each case, the conductor tracks can extend from the corresponding contact vias to the integrated circuit or to the optoelectronic compo-nent across the gap between the side surfaces of the cavities and the integrated circuit or the optoelectronic component.

In some embodiments, the carrier substrate or printed circuit board may be multilayered so that the cavities can be inserted into the carrier substrate at the desired depth without creating holes in the carrier substrate.

The integrated circuit and/or the sensor element and/or the optoelectronic component can each be glued into the correspond-ing cavity by means of an adhesive. For example, the integrated circuit and/or the sensor element and/or the optoelectronic component may be bonded to an electrically conductive contact pad of the carrier substrate by means of an electrically conductive adhesive. Furthermore, the integrated circuit or the sensor element and/or the optoelectronic component may be bonded or soldered to an electrically conductive contact pad of the carrier substrate. The connection between the integrated circuit or sensor element and the carrier substrate and/or the connection between the optoelectronic device and the carrier substrate may be characterized by the integrated circuit or sensor element and/or optoelectronic device being fixed in the cavity and optionally having electrically conductive proper-ties.

In some embodiments, the carrier substrate may have at least one third contact via extending through the carrier substrate in the region of at least one of the cavities. An electrically conductive contact pad may be disposed at the bottom of the at least one cavity and connected to the integrated circuit or sensor element or optoelectronic device, such that the integrated circuit or sensor element and/or optoelectronic device may be electrically connected via the third contact via.

Individual aspects and features of the preceding embodiments and examples may be readily combined with each other without affecting the principle of the invention. Further, aspects and features of the preceding embodiments and examples may be com-bined with the further sensor device now described without thereby compromising the principle of the invention. This in-cludes, among other things, the type and design of the integrated circuit or the at least one sensor element and the at least one opto-electronic component, as well as the type and design of the conductor tracks.

A further sensor device according to the invention comprises a carrier substrate, in particular a lead frame, with at least a first and a second electrical contact region. An integrated circuit is arranged on the top surface of the first electrical contact region and at least one sensor element is arranged on or integrated into the integrated circuit. The sensor device further comprises at least one light-emitting element or opto-electronic component, which is arranged on the integrated circuit at a distance from the at least one sensor element. A first electrical lead, in particular a bonding wire, electrically connects the second electrical contact region and the integrated circuit to each other, and a substantially opaque first encapsulation material laterally surrounds the at least one sensor element and the at least one optoelectronic device such that at least one surface of the at least one sensor element and the at least one optoelectronic device opposite the lead frame remains uncovered by the opaque encapsulation material.

In some embodiments, the substantially opaque first encapsula-tion material also surrounds the at least one first and the at least one second electrical contact regions. In particular, the at least one first electrical contact region and the at least one second electrical contact region are mechanically bonded together by the substantially opaque first encapsulation mate-rial.

In some embodiments, a cavity or window is formed in the sub-stantially opaque first encapsulation material over the at least one sensor element through which light from the environment can impinge on the sensing element.

In some embodiments, a photosensitive region of the sensor element is disposed in a plane that is different from a plane in which the light-emitting region of the optoelectronic device lies. In particular, the plane in which the light-emitting re-Bion of the optoelectronic component lies is arranged parallel to and spaced apart from the plane in which the photosensitive region of the sensor element lies. By arranging the optoelectronic component on the integrated circuit, the plane in which the light-emitting region lies is, for example, further away from the carrier substrate than the plane in which the photosensitive region lies.

Such an arrangement can reduce crosstalk of the sensing device because the side surfaces of the cavities or window, and thus the substantially opaque first encapsulation material, act as a partition or diaphragm between the sensor element and the optoelectronic device, such that a direct path of light emitted from the optoelectronic device to the sensor element is inter-rupted.

In some embodiments, the window or cavity is filled with an at least partially transparent material. This can, for example, ensure that the photosensitive region of the at least one sensor element is not damaged by external influences. For example, mechanical damage or damage caused by noxious gas can thus be prevented.

In some embodiments, the substantially opaque first encapsula-tion material is substantially flush with a surface of the at least one optoelectronic device opposite the lead frame. In particular, the substantially opaque first encapsulation mate-rial forms a potting layer in which the at least one optoelectronic device, the integrated circuit, and the carrier substrate are embedded. A surface of the at least one optoelectronic component facing the carrier substrate is in the same plane as a surface of the substantially opaque first encapsulation ma-terial facing the carrier substrate.

In some embodiments, at least a first electrical contact of the at least one optoelectronic component is electrically connected to the integrated circuit by means of a planar interconnect or a solder pad. The planar interconnect can be designed according to at least one of the above embodiments. In particular, the planar interconnect can be arranged between a first electrical contact of the at least one optoelectronic component and the integrated circuit. The at least one optoelectronic device may then be electrically connected to the planar interconnect by means of a solder connection, such as a SAC solder connection. Accordingly, the planar interconnect may serve to provide a contact layer rather than a conductive path in the classical sense.

In some embodiments, the at least one optoelectronic device is formed in the form of a flip chip. A second electrical contact of the at least one optoelectronic component may be electrically connected to the integrated circuit by means of a further planar interconnect or a further solder pad.

In some embodiments, at least a second electrical contact of the at least one optoelectronic device is electrically connected to the integrated circuit by means of a bonding wire. In particular, this may be the case if the at least one optoelectronic device has a top surface contact and a bottom surface contact, for example in the form of a VCSEL. In this case, the sensor device may further comprise an additional cavity or window above the at least one optoelectronic component.

### BRIEF DESCRIPTION OF THE DRAWINGS

In the following, embodiments of the invention are explained in more detail with reference to the accompanying drawings. They show, schematically in each case,

FIG. 1 a sectional view of a sensor device accord-ing to the proposed principle;

FIG. 2 a top view of a sensor device according to the proposed principle;

FIG. 3 to FIG. 8 sectional views of various examples of a sensor device according to the proposed principle;

FIG. 9 a sectional view of a further sensor device according to the proposed principle;

FIG. 10 a sectional view of a further embodiment of a further sensor device according to the proposed principle;

FIG. 11 a sectional view of a further sensor device according to the proposed principle;

FIG. 12 a sectional view of a further example of a further sensor device according to the pro-posed principle; and

FIGS. 13 and 14 each a sectional view and a top view of a further embodiment example of a further sen-sor device according to the proposed prin-ciple.

### DETAILED DESCRIPTION

The following embodiments and examples show different aspects and their combinations according to the proposed principle. The embodiments and examples are not always to scale. Likewise, various elements may be shown enlarged or reduced in size to emphasize individual aspects. It goes without saying that the individual aspects and features of the embodiments and examples shown in the figures can be readily combined with each other without affecting the principle of the invention. Some aspects have a regular structure or shape. It should be noted that minor deviations from the ideal shape may occur in practice, but without contradicting the inventive idea.

In addition, the individual figures, features and aspects are not necessarily shown in the correct size, nor do the propor-tions between the individual elements have to be fundamentally correct. Some aspects and features are emphasized by showing them enlarged. However, terms such as “above”, “above”, “below”, “below-half”, “larger”, “smaller” and the like are correctly represented in relation to the elements in the figures. Thus, it is possible to derive such relationships between the elements based on the figures.

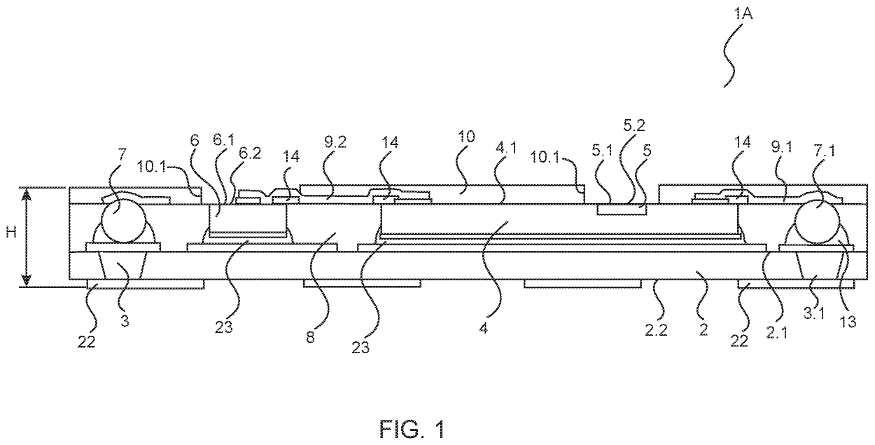

FIG. 1 shows a sectional view of a sensor device 1a according to the proposed principle. The sensor device 1 comprises a printed circuit board 2 having a top surface 2.1 and a bottom surface 2.2, and at least one contact via 3 in the printed circuit board 2. In the sectional view of the sensor device shown, the latter has two contact via 3, 3.1, which are formed in such a way that they guide an electrical contact from the bottom surface 2.2 to the top surface 2.1 of the printed circuit board. At the ends of the contact vias 3, 3.1, connection con-tacts 22 are provided on the bottom surface 2.2 of the printed circuit board, by means of which the sensor device can be elec-trically contacted.

An electrically conductive contact element in the form of a metallic ellipsoid 7, 7.1, for example in the form of a Cu ball or Cu core ball, is applied to each of the contact vias 3, 3.1 by means of a SAC solder connection 13 and electrically con-nected to it.

Furthermore, an integrated circuit 4 is arranged on the top surface 2.1 of the printed circuit board 2. A sensor element 5, in particular a photodetector, is integrated in the integrated circuit. The sensor element 5 is integrated into the integrated circuit in such a way that the photosensitive region 5.2 of the photodetector 5 is located within the surface 4.1 of the integrated circuit 4 opposite the carrier substrate. The integrated circuit 4 comprises a bottom contact and a plurality of contact pads on its top surface 4.1, and is fixed by means of an adhesive 23, in particular an electrically conductive adhesive, with the bottom contact on a contact pad of the printed circuit board 2 and is electrically connected thereto.

At a distance from the integrated circuit 4 or the sensor element 5 integrated in the integrated circuit 4, a light-emitting or optoelectronic component 6 is arranged on the top surface 2.1 of the printed circuit board 2. The optoelectronic component 6 has a top surface contact and a bottom surface contact and is attached by means of an adhesive 23, in particular an electrically conductive adhesive, to the bottom surface contact on a contact pad of the printed circuit board 2 and electrically connected to the latter.

The integrated circuit 4 including the sensor element 5, the optoelectronic component 6 and the metallic ellipsoids 7, 7.1 are surrounded in lateral direction by an substantially opaque first encapsulation material 8. The first encapsulation mate-rial 8 accordingly forms a potting layer arranged on the printed circuit board 2, in which the integrated circuit 4 including the sensor element 5, the optoelectronic component 6 and the metallic ellipsoids 7, 7.1 are embedded. The integrated circuit 4 including the sensor element 5 and the optoelectronic compo-nent 6 are embedded in the first encapsulation material 8 in such a way that the surface 5.1 of the sensor element 5 opposite the carrier substrate 2 and the surface 6.1 of the optoelectronic component 6 opposite the carrier substrate 2 are not covered by the first encapsulation material 8, and the first encapsulation material 8 is substantially flush with the top surface of the sensor element 5, the optoelectronic component 6 and the integrated circuit 4 respectively.

Only an edge region of the metallic ellipsoids 7, 7.1, the top contact of the optoelectronic component 6, and the several contact pads on the top surface 4.1 of the integrated circuit 4 protrude above the first encapsulation material 8.

By means of a first conductor track 9.1, the first metallic ellipsoid 7.1 is electrically connected to a contact pad on the top surface 4.1 of the integrated circuit 4. By means of a second conductor track 9.2, the top surface contact of the optoelectronic component 6 is electrically connected to another contact pad on the top surface 4.1 of the integrated circuit 4.

An insulating layer 14 is formed between each of the conductor tracks 9.1, 9.2 and the top surface 4.1 of the integrated circuit 4 or the top surface 6.1 of the optoelectronic component 6. The insulation layer 14 is arranged on the top surface 4.1 of the integrated circuit 4 or the top surface 6.1 of the optoelectronic component 6 in such a way that the conductor tracks 9.1, 9.2 electrically contact a contact pad of the integrated circuit 4 or the top surface contact of the optoelectronic component 6, but are electrically insulated from the top surface 4.1 of the integrated circuit 4 or the top surface 6.1 of the optoelectronic component 6.

A structured layer 10 of an substantially opaque material, in particular a black photostructurable epoxy or acrylic lacquer, is additionally arranged on the first encapsulation material 8 or on the conductor tracks 9.1, 9.2. The structured layer 10 is arranged in such a way that the photosensitive region 5.2 of the sensor element 5 and the light-emitting region 6.2 of the optoelectronic component 6 are not covered by the structured layer 10, i.e. the structured layer 10 is recessed in these areas.

This can be advantageous in particular because it results in a refractive index jump between the structured layer 10 and the surrounding atmosphere at the side surfaces 10.1 of the structured layer 10, which are formed adjacent to the photosensitive region 5.2 and the light-emitting region 6.2. This refractive index jump increases the reflectivity of the side surfaces 10.1, for example, and crosstalk of the sensor device can be reduced.

The individual components and layers of the sensor device are selected and arranged in such a way that the sensor device does not exceed a total height H of 400 μm or 360 μm.

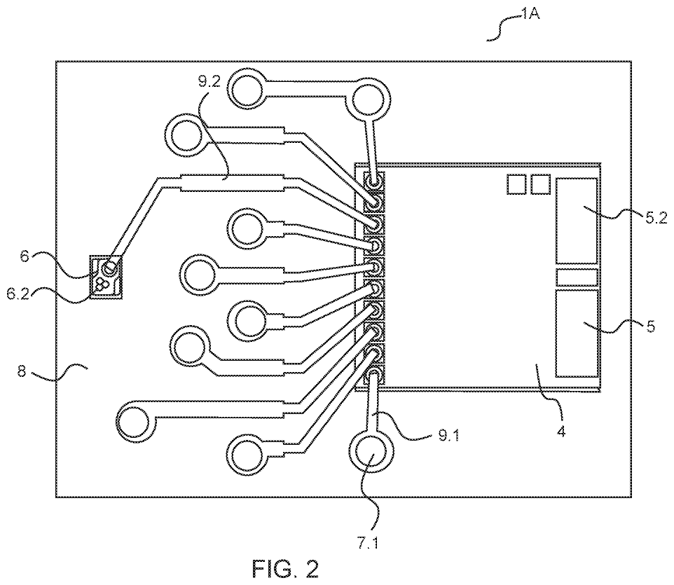

FIG. 2 shows a top view of a sensor device 1A according to the proposed principle. Shown are several contact pads on the top surface 4.1 of an integrated circuit 4, each of which is elec-trically connected via a conductor track 9, 9.1, 9.2 to an electrically conductive contact element in the form of a metallic ellipsoid 7, 7.1 or to an optoelectronic component 6. A sensor element 5, in particular a photodetector, is integrated in the integrated circuit 4. The photosensitive region 5.2 of the sensor element 5 is formed in a partial area, in particular an edge area, of a top surface 4.1 of the integrated circuit 4. In the present case, the photosensitive region 5.2 is formed by 3 partial areas, each of which can be sensitive to light of different wavelengths, or sensitive to light of the same wavelength.

The integrated circuit 4 or the sensor element 5 integrated in the integrated circuit 4, the metallic ellipsoids 7, 7.1, and the optoelectronic component 6 are embedded in a substantially opaque first encapsulation material 8, and the substantially opaque first encapsulation material 8 forms the outer contour of the sensor element 1A, at least as seen in plan view.

The optoelectronic component 6, in particular the light-emitting region 6.2 of the optoelectronic component 6, is arranged at a distance from the integrated circuit 4 or the sensor element 5 integrated in the integrated circuit 4, and the substan-tially opaque first encapsulation material 8 extends between the optoelectronic component 6 and the integrated circuit 4.

The conductor tracks 9, 9.1, 9.2 have different widths over their longitudinal extension direction. In particular, the con-ductor tracks have a smaller width in the area of contact with the contact pads on the top surface 4.1 of the integrated circuit 4, so that the individual conductor tracks are electrically insulated from one another and the risk of a short circuit between the conductor tracks is reduced. On the other hand, in a region more distant from the contact pads on the upper surface 4.1 of the integrated circuit 4, the conductor tracks have a larger width to improve the thermal characteristics of the sen-sor device 1A.

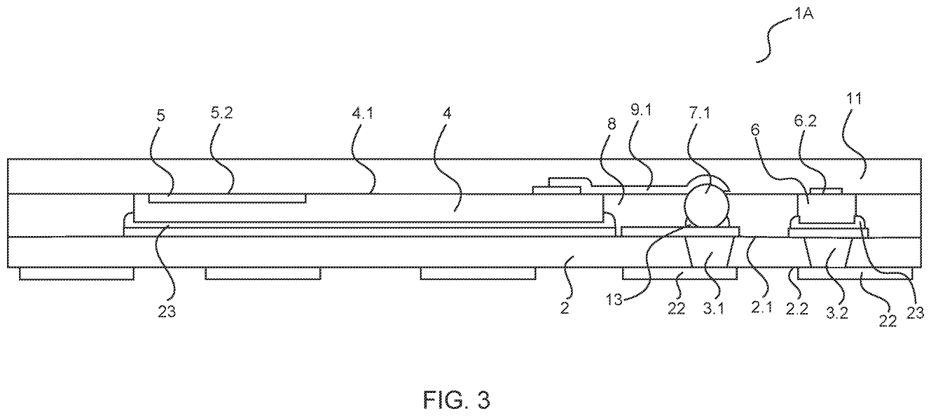

FIG. 3 shows a sectional view of a further embodiment form of a sensor device 1A, which differs from the sensor device of FIG. 1 in that it does not have a structured layer 10, but an at least partially transparent material 11, in particular a layer of an at least partially transparent material. The layer of at least partially transparent material 11 is formed on the first encapsulation material 8 or on the conductive track 9.1.

Furthermore, in contrast to the sensor device shown in FIG. 1, the sensor device 1A does not have a second conductor track 9.2 (at least not in the sectional view shown), which electrically connects the optoelectronic component 6 to the integrated circuit 4, but a second contact via 3.2 is formed in the printed circuit board 2, via which the optoelectronic component 6 is electrically contacted.

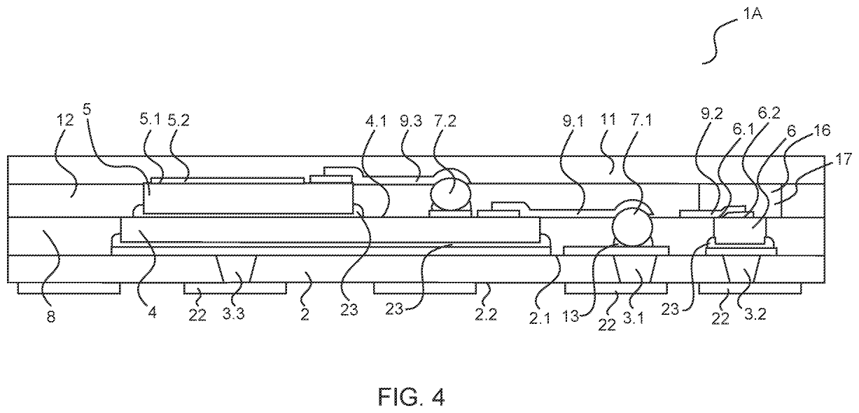

FIG. 4 shows an example of an embodiment in which the sensor element 5 is not integrated in the integrated circuit 4, but is arranged on its top surface 4.1, in particular glued on by means of an adhesive 23. Electrical contacting of the sensor element 5 is effected in that a second electrically conductive contact element in the form of a metallic ellipsoid 7.2 is arranged on one of the contact pads on the top surface 4.1 of the integrated circuit 4 and is electrically connected thereto, and the second metallic ellipsoid 7.2 and the sensor element 5 are electrically connected to one another by means of a third conductor track 9.3.

The arrangement of the sensor element 5 on the top surface 4.1 of the integrated circuit 4 results in a plane above the first encapsulation material 8, so to speak. The sensor element 5 and the second metallic ellipsoid 7.2 are surrounded in this plane in the lateral direction by a substantially opaque second en-capsulation material 12. The second encapsulation material 12 accordingly forms a further potting layer arranged above the first encapsulation material 8, in which the sensor element 5 and the second metallic ellipsoid 7.2 are embedded. The sensor element 5 is embedded in the second encapsulation material 12 in such a way that the surface 5.1 of the sensor element 5 opposite the carrier substrate 2 is not covered by the second encapsulation material 12, and the second encapsulation mate-rial 12 is substantially flush with the top surface of the sensor element 5. The third conductor track 9.3 is formed on the second encapsulation material 12.

Above the optoelectronic component 6, in particular above the light-emitting region 6.2 of the optoelectronic component 6, a window 16 or a recess is formed in the second encapsulation material 12. Correspondingly, the second encapsulation material 12 also does not cover a surface 6.1 of the optoelectronic component 6 opposite the carrier substrate 2 or the light-emitting region 6.2 of the optoelectronic component 6, respectively. The window 16 can, for example, be filled with the same at least partially transparent material 11 that is formed on the second encapsulation material 12 or on the conductor track 9.3, or the window 16 can be filled with another at least partially transparent material such as a glass chip 17.

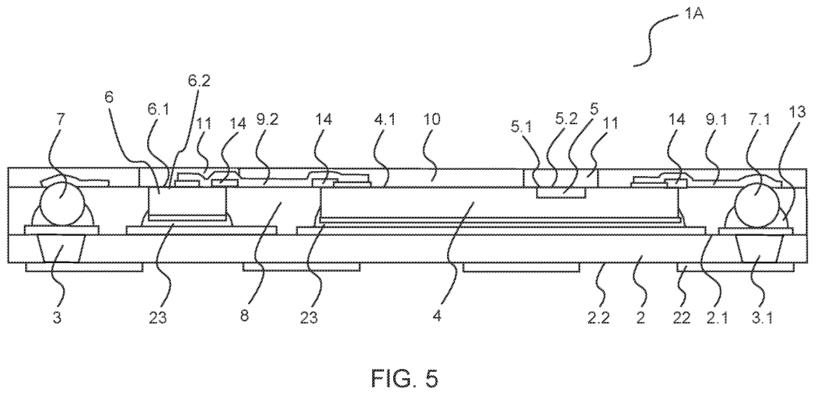

FIG. 5 shows a sectional view of a further embodiment of a sensor device 1A, which differs from the sensor device of FIG. 1 in that the areas recessed in the structured layer 10 above the photosensitive region 5.2 of the sensor element 5 and the light-emitting region 6.2 of the optoelectronic component 6 are filled with an at least partially transparent material 11. This makes it possible, for example, to ensure that the photosensitive region 5.2 of the at least one sensor element 5 and the light-emitting region 6.2 of the at least one optoelectronic component 6 are not damaged by external influences.

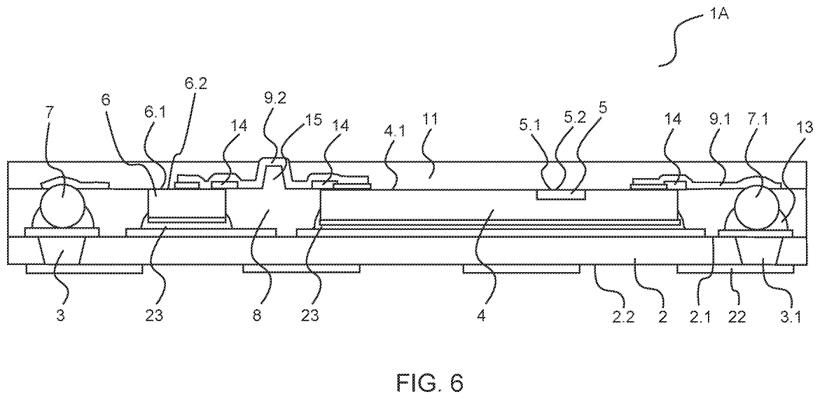

FIG. 6 shows a sectional view of a further embodiment form of a sensor device 1A, which differs from the sensor device of FIG. 1 in that it does not have a structured layer 10, but an at least partially transparent material 11, in particular a layer of an at least partially transparent material. The layer of at least partially transparent material 11 is formed on the first encapsulation material 8 or on the conductor tracks 9.1, 9.2.

Furthermore, in contrast to the sensor device shown in FIG. 1, the sensor device 1A comprises a protrusion 15 or a dam in an area between the sensor element 5 and the optoelectronic component 6, which projects beyond the optoelectronic component 6 and the sensor element 5. The protrusion 15 can, for example, take place in the same process step as an application of the substantially opaque first encapsulation material 8 to the car-rier substrate and accordingly be formed from the same material, or the protrusion 15 can be applied in a further step to an already existing layer of the first encapsulation material 8. In the latter case, the material of the protrusion 15 can differ from the first encapsulation material 8, for example.

To increase the reflectivity of the protrusion 15, the second conductor track 9.2 runs on the protrusion 15, so that a cross-talk of the sensor device 1A can be reduced.

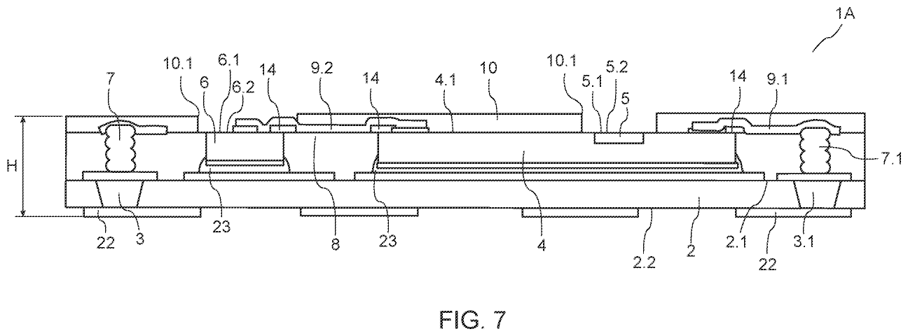

FIG. 7 shows a sectional view of a further embodiment of a sensor device 1A, which differs from the sensor device of FIG. 1 in that an electrically conductive contact element in the form of a stud bump pillar 7, 7.1 is applied to and electrically connected to each of the contact vias 3, 3.1. In the illustra-tion in FIG. 7, the stud bump pillars 7, 7.1 each have four stud bumps which are stacked on top of one another and which extend from the respective contact via 3, 3.1 through the first encapsulation material 8. The height of the stud bump pillars 7, 7.1 is substantially identical and only one edge region of each stud bump pillar 7, 7.1 protrudes beyond the first encapsulation material 8.

By means of a first conductor track 9.1, the first stud bump pillar 7.1 is electrically connected to a contact pad on the top surface 4.1 of the integrated circuit 4, and by means of a second conductor track 9.2, the top surface contact of the optoelectronic component 6 is electrically connected to a further contact pad on the top surface 4.1 of the integrated circuit 4.

The stud bumps of the stud bump pillars 7, 7.1 can be produced, for example, by a nailhead wirebonding process or ball bonding process, in which a nailhead or ball is produced on the carrier substrate with a wirebonder and the wire running out of the wirebonder for producing the nailhead or ball is torn off directly above the nailhead or ball. This creates a so-called “stud bump” or “nailhead”. Several such stud bumps or nailheads can be stacked or arranged to form a pillar. For example, a single stud bump may have a height of less than or equal to 50 μm, less than or equal to 30 μm, or less than or equal to 20 μm. Such a process can be used, for example, to produce electrically conductive contact elements simply and inexpensively using an already known nailhead-wirebond process or ball-bond process. Depending on the number of stud bumps stacked on top of one another, these elements can have a desired height with rela-tively high accuracy.

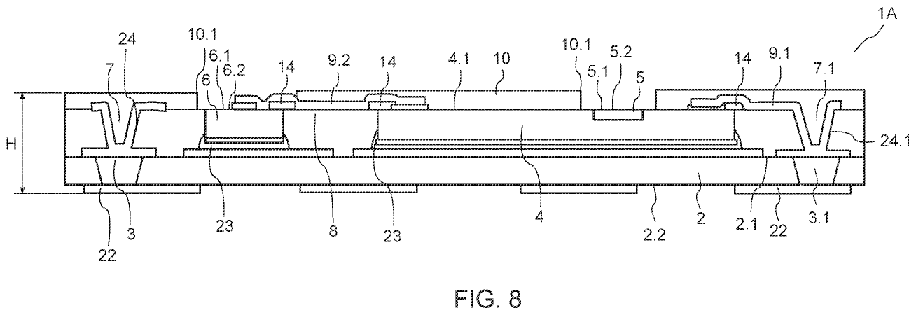

FIG. 8 shows a sectional view of a further embodiment of a sensor device 1A, which differs from the sensor device of FIG. 1 in that an electrically conductive contact element 7, 7.1 in the form of an opening 24 is applied to each of the contact via 3, 3.1 through the first encapsulation material 8 with metallized side surfaces and is electrically connected thereto. The openings 24 can each be created in the first encapsulation material 8 by a laser ablation process. When the first conductor track 9.1 is applied to the first encapsulation material 8 in the area of the first opening 24.1, the side surfaces of the opening 24.1 are simultaneously covered by means of the same material as the conductor track 9.1 and thereby metallized. Furthermore, the application of the first conductor track 9.1 establishes electrical contact with the contact via 3.1 located below the opening. The opening 24.1 is formed directly above the contact via 3.1 and tapers in the direction of the contact via 3.1. The opening extends from an top surface of the first encapsulation material 8 facing away from the carrier substrate 2 through the first encapsulation material to an top surface of the first encapsulation material 8 facing the carrier substrate 2. The opening diameter of the opening 24.1 on the top surface of the first encapsulation material 8 facing away from the carrier substrate 2 is larger than the opening diameter of the opening 24.1 on the top surface of the first encapsulation material 8 facing the carrier substrate 2.

The metallized opening is filled in the course of applying the structured layer 10 of the substantially opaque material. Accordingly, the structured layer 10 is arranged in such a way that the photosensitive region 5.2 of the sensor element 5 and the light-emitting region 6.2 of the optoelectronic component 6 are not covered by the structured layer 10, i.e. the structured layer 10 is recessed in these areas, and the metallized openings are filled by the material of the structured layer 10.

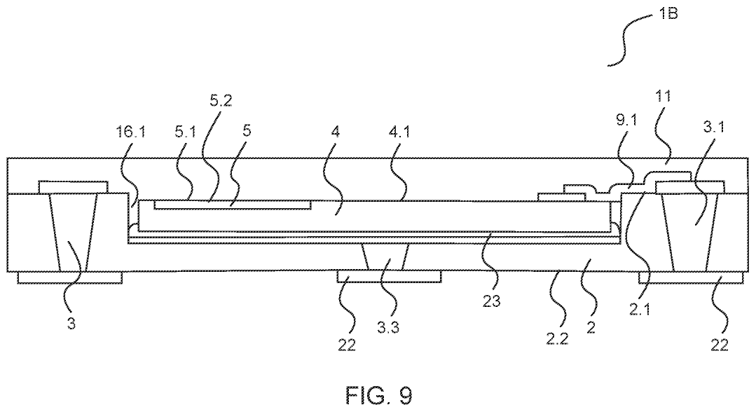

FIG. 9 shows a sectional view of another sensor device 1B according to the proposed principle. The sensor device comprises a carrier substrate 2, in particular a printed circuit board, which in addition to the contact vias 3, 3.1 of the previous embodiments comprises a first cavity 16.1 in which an integrated circuit 4 and a sensor element 5 integrated therein are arranged. The ladder plate 2 is, for example, of multilayer design and accordingly has a greater thickness.

The first cavity 16.1 is designed in such a way that the integrated circuit 4 including the sensor element 5 integrated therein does not protrude beyond the top surface 2.1 of the printed circuit board.

This arrangement means that, in contrast to the previous embodiment examples, metallic ellipsoids can be dispensed with, since contact pads on the top surface 4.1 of the integrated circuit 4 lie in substantially the same plane as the ends of the contact vias 3, 3.1. Accordingly, a first conductor track 9.1 can extend directly from the first contact via 3.1 to a contact pad on the top surface of the integrated circuit 4.

An at least partially transparent material 11, in particular a layer of an at least partially transparent material, is formed on the printed circuit board 2 or on the integrated circuit 4 and the first conductor track 9.1.

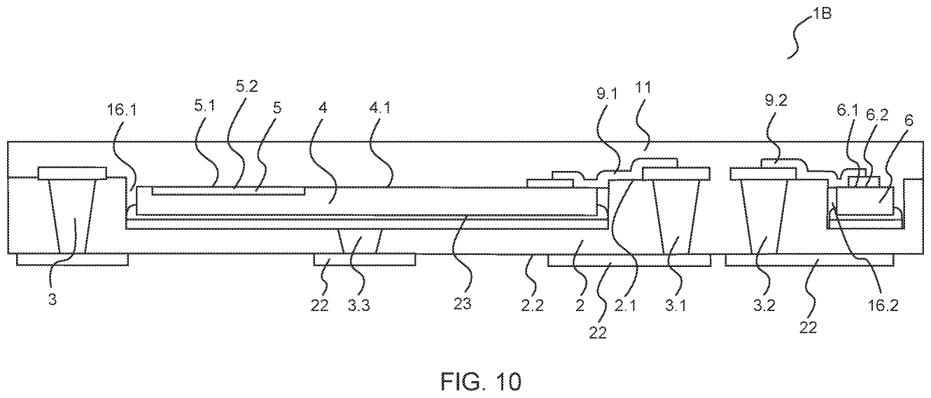

FIG. 10 shows the sensor device 1B of FIG. 9, in which the circuit board has a second cavity 16.2 in which an optoelectronic component 6 is arranged. The second cavity 16.1 is formed in such a way that the optoelectronic component 6 or the light-emitting region 6.2 of the optoelectronic component 6 does not project beyond the top surface 2.1 of the printed circuit board. The printed circuit board also has a second contact via 3.2, which is electrically connected to the optoelectronic component 6 via a second conductor track 9.2.

By “recessing” the integrated circuit 4 and the optoelectronic component 6 in the circuit board 2, the direct path of the light emitted from the optoelectronic component to the sensor element can be interrupted and crosstalk of the sensor device 1B can be reduced.

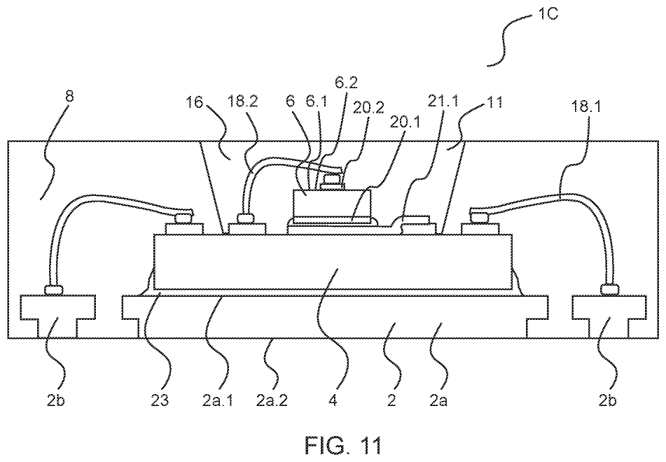

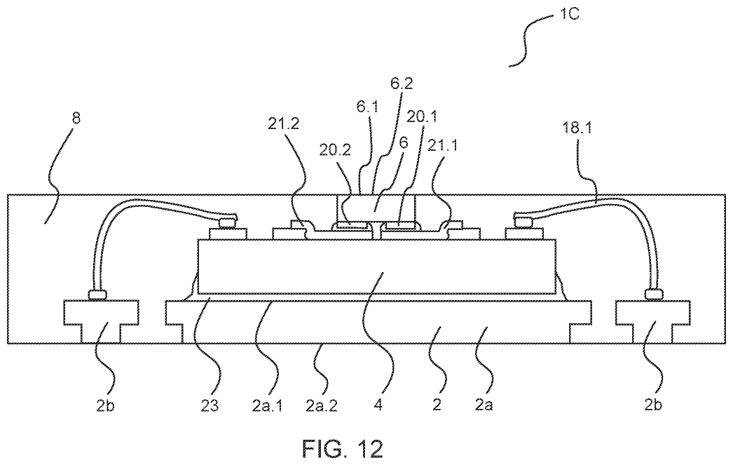

FIG. 11 and FIG. 12 each show a sectional view of another sensor device 1C according to the proposed principle. The sensor device 1C comprises a carrier substrate 2, in particular a lead frame, with a first 2a and two second 2b electrical contact regions. An integrated circuit 4 is arranged on the top surface 4.1 of the first electrical contact region 2a and a sensor element 5, in particular a photodetector, is integrated in the integrated circuit 4. The sensor device 1C further comprises an optoelectronic component 6 arranged on the integrated circuit 4.

The integrated circuit 4 or contact pads on the top surface 4.1 of the integrated circuit 4 are electrically connected by means of a bonding wire 18.1 to a second electrical contact region 2b, respectively. The integrated circuit 4 is attached to the top surface of the first electrical contact region 2a by means of an adhesive 23. The adhesive can optionally have electrically conductive properties so that the integrated circuit 4 is also electrically connected to the first electrical contact region 2a.

The light-emitting or optoelectronic component 6 is arranged adjacent to the sensor element 5 integrated in the integrated circuit on the top surface 4.1 of the integrated circuit 4, so that the photosensitive region 5.2 of the sensor element and the light-emitting region 6.2 of the optoelectronic component 6 are arranged adjacent to one another in different planes lying parallel to one another.

A substantially opaque first encapsulation material 8 laterally encloses the integrated circuit 4 including the integrated sen-sor element 5, the optoelectronic component 6, and the lead frame 2. In particular, the electrical contact regions are mechanically connected to each other by the substantially opaque first encapsulation material 8 and the bonding wires 18.1 are protected from mechanical impact.

The first encapsulation material encloses the intergated circuit 4 including the integrated sensor element 5 and the opto-electronic component 6 in such a way that a surface 5.1 of the sensor element 5 opposite the lead frame 2 and a surface 6.1 of the optoelectronic component 6 opposite the lead frame 2 remain uncovered by the opaque encapsulation material 8.

At least a first electrical contact 20.1 of the optoelectronic component 6 is electrically connected to the integrated circuit by means of a first planar interconnect 21.1 or, for example, a solder pad. The first planar interconnect 20.1 is arranged between the first electrical contact 20.1 and the integrated circuit 4 and is in the form of a contact layer applied to the integrated circuit 4. The optoelectronic component 6 is then electrically connected to the first planar interconnect 21.1 by means of a solder connection such as a SAC solder connection.

In the case of the sensor device 1C of FIG. 11, the optoelectronic component 6 is formed such that a second electrical contact 20.2 is arranged on a surface of the optoelectronic component 6 opposite the first electrical contact 20.1. This can be the case in particular if the at least one light-emitting element has a top-side contact and a bottom-side contact, for example in the form of a VCSEL. The second electrical contact 20.2 is electrically connected to the integrated circuit by means of a further bonding wire 18.2.

Furthermore, the first encapsulation material 8 has a window 16 or recess above or around the optoelectronic component 6. The window can, for example, be filled with an at least partially transparent material 11. The window or recess creates a partition between the optoelectronic component 6 and the sensor element, which is formed by the first encapsulation material 8. Accordingly, a direct path of the light emitted by the opto-electronic component 6 to the sensor element 5 is interrupted. The filling of the window 16 with the at least partially transparent material 11 can serve to protect the further bonding wire 18.2 as well as the optoelectronic component 6 from, for example, mechanical impact.

In the case of the sensor device 1C of FIG. 12, the light-emitting element 6 is in the form of a flip chip. A second electrical contact 20.2 of the optoelectronic component 6 is arranged on the same side of the optoelectronic component 6 as the first electrical contact 20.1. Like the first electrical contact 20.1, the second electrical contact 20.2 is electrically connected to the integrated circuit 4 by means of a second planar interconnect 21.2.

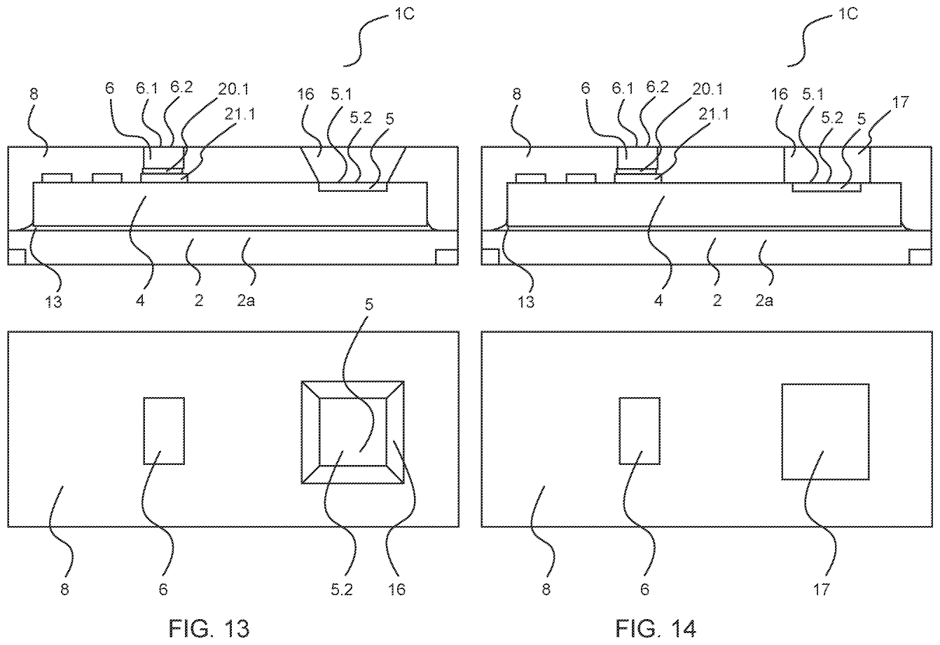

The substantially opaque first encapsulation material 8 is sub-stantially planar with a surface of the optoelectronic component 6 opposite the lead frame 2, that is, the top surface 6.1 of the optoelectronic component 6. Accordingly, the top surface 6.1 of the optoelectronic component 6 lies in the same plane as a surface of the first encapsulation material 8, which is sub-stantially opaque, opposite the carrier substrate. FIGS. 13 and 14 show, respectively, a sectional view and a top view of two embodiments of the sensor device 1C shown in FIG. 12.

The sensor devices 1C comprise a cavity or window 16 in the first encapsulation material 8 over the sensor element 5 or over a sensitive area 5.2 of the sensor element 5.

The cavity or window 16 may be filled with an at least partially transparent material 11. Alternatively, a glass chip 17 can be formed in the window as shown in FIG. 12. In this way, for example, it can be achieved that the sensitive area 5.2 of the sensor element 5 is not damaged by external influences, or that certain wavelengths can be filtered out of the incident light spectrum.

Such an arrangement can reduce crosstalk of the sensing device 1C, since the side surfaces of the cavity or window 16, and thus the substantially opaque first encapsulation material 8, act as a partition or diaphragm between the sensor element 5 and the optoelectronic component 6, so that a direct path of light emitted by the optoelectronic device to the sensor element is interrupted.

### REFERENCE LIST

1A, 1B, 1C sensor device
2 carrier substrate, printed circuit board, lead frame
2.1 top surface
2.2 bottom surface
2a first electrical contact region
2b second electrical contact region
2a.1 top surface
2b.2 bottom surface
3, 3.1, 3.2, 3.3 contact via
4 integrated circuit
4.1 top surface
5 sensor element
5.1 top surface
5.2 photosensitive region
6 light emitting element
6.1 top surface
6.2 light-emitting region
7, 7.1, 7.2 electrically conductive contact element, metallic ellipsoid, stud-bump pillar
8 substantially opaque first encapsulation material
9, 9.1, 9.2, 9.3 conductor track
10 structured layer
10.1 side surface
11 at least partially transparent material
12 substantially opaque second encapsulation material
13 solder connection
14 insulation layer
15 elevation
16 window, cavity
16.1 first cavity
16.2 second cavity
17 glass chip
18.1, 18.2 electrical lead, bonding wire
20.1, 20.2 electrical contact
21.1, 21.2 planar interconnect
22 connection contact
23 adhesive
24, 24.1 opening
H total height

1. A sensor device comprising:
a carrier substrate having at least one contact via for guiding an electrical contact from a bottom surface to a top surface of the carrier substrate;
an integrated circuit arranged on the top surface of the carrier substrate;
at least one sensor element arranged on or integrated into the integrated circuit;
at least one optoelectronic component arranged on the top surface of the carrier substrate at a distance from the integrated circuit;
at least one first electrically conductive contact element arranged on the at least one contact via and electrically connected thereto;
a substantially opaque first encapsulation material, which encloses the at least one sensor element, the at least one optoelectronic component, and the at least one first electrically conductive contact element in lateral direction in such a way that at least one surface of the at least one sensor element and of the at least one optoelectronic component opposite the carrier substrate remains uncovered by the substantially opaque first encapsulation material;
at least one first conductor track formed on the substantially opaque first encapsulation material and electrically connecting the at least one first electrically conductive contact element and the integrated circuit, and
at least one second conductor track formed on the substantially opaque first encapsulation material and electrically connecting the integrated circuit with the at least one optoelectronic component.

2. Sensor The sensor device according to claim 1,
wherein a structured layer of a substantially opaque material is arranged on the substantially opaque first encapsulation material in such a way that the photosensitive region of the at least one sensor element and the light-emitting region of the at least one optoelectronic component remain uncovered of the substantially opaque material of the structured layer.

3. The sensor device according to claim 2,
wherein the structured layer of the substantially opaque material comprises a photostructurable lacquer, in particular a black photostructurable epoxy or acrylic lacquer.

4. The sensor device according to claim 1,
wherein at least the photosensitive region of the at least one sensor element and the light-emitting region of the at least one optoelectronic component remain uncovered.

5. The sensor device according to claim 2,
wherein the photosensitive region of the at least one sensor element and the light-emitting region of the at least one optoelectronic component are covered by an at least partially transparent material.

6. The sensor device according to claim 1,
wherein a total height of the sensor device does not exceed 400 μm.

7. The sensor device according to claim 1,
wherein the at least one optoelectronic device is formed by an infrared light emitting VCSEL or an infrared light emitting LED.

8. The sensor device according to claim 1,
wherein the at least one sensor element is arranged on the integrated circuit and the substantially opaque first encapsulation material is substantially flush with a surface of the at least one optoelectronic component and of the integrated circuit opposite the carrier substrate.

9. The sensor device according to claim 8,
wherein at least one second electrically conductive contact element is arranged on the integrated circuit and a substantially opaque second encapsulation material encloses the at least one sensor element and the at least one second electrically conductive contact element in the lateral direction in such a way that at least the light-emitting region of the at least one optoelectronic component and a surface of the at least one sensor element opposite the carrier substrate remain uncovered by the substantially opaque second encapsulation material.

10. The sensor device according to claim 9,
wherein at least one third conductor track is formed on the substantially opaque second encapsulation material electrically connecting the at least one sensor element with the at least one second electrically conductive contact element.

11. The sensor device according to claim 8,
wherein a window is formed in the substantially opaque second encapsulation material above the at least one optoelectronic component.

12. The sensor device according to claim 11,
wherein the window is filled with an at least partially transparent material.

13. The sensor device according to claim 1,
wherein an at least partially transparent encapsulation material is arranged on the substantially opaque first encapsulation material or on the substantially opaque second encapsulation material, which covers at least the at least one sensor element.

14. The sensor device according to claim 1,
wherein the substantially opaque first encapsulation material comprises, in a region between the at least one sensor element and the at least one optoelectronic component, an elevation, in particular a dam, which projects beyond the at least one optoelectronic component and the at least one sensor element.

15. The sensor device according to claim 1,
wherein at least one of the at least one first, the at least one second and the at least one third conductor track is formed by a planar interconnect.

16. The sensor device according to claim 1,
wherein at least one of the at least one first and the at least one second electrically conductive contact element is formed by a metallic ellipsoid.

17. The sensor device according to claim 1,
wherein at least one of the at least one first and the at least one second electrically conductive contact element is formed by at least two stud bumps stacked on top of each other or by at least two nailheads produced by a ball bonding method.

18. The sensor device according to claim 1,
wherein at least one of the at least one first and the at least one second electrically conductive contact element is formed by an opening through the substantially opaque first encapsulation material, the side surfaces of which are metallized.

19. A sensor device comprising:
a carrier substrate having at least one contact via for guiding an electrical contact from a bottom surface to a top surface of the carrier substrate and at least one first cavity;
an integrated circuit arranged in the first cavity;
at least one sensor element arranged on or integrated into the integrated circuit; and
a first conductor track formed on the carrier substrate and electrically connecting the at least one contact via with the integrated circuit; and
an at least partially transparent encapsulation material covering at least the integrated circuit and the first conductor track.

20. The sensor device according to claim 19,
wherein the carrier substrate comprises at least a second cavity in which an optoelectronic component is arranged.

21. The sensor device according to claim 20,
wherein the carrier substrate comprises at least one further contact via and a second conductor track, and
wherein the second conductor track is formed on the carrier substrate and electrically connects the at least one further contact via with the optoelectronic component.

22. The sensor device according to claim 19,
wherein at least the first cavity is formed such that a top surface of the integrated circuit does not project beyond the top surface of the carrier substrate.

23. The sensor device according to claim 19,
wherein at least the at least one first conductor track is formed by a planar interconnect.

24. The sensor device according to claim 19,
wherein the at least one optoelectronic component is formed by an infrared light emitting VCSEL or an infrared light emitting LED.

25. A sensor device comprising:
a lead frame having at least a first and a second electrical contact region;
an integrated circuit arranged on the top surface of the first electrical contact region;
at least one sensor element integrated in the integrated circuit;
at least one optoelectronic component arranged on the integrated circuit at a distance from the at least one sensor element;
a first electrical lead, in particular a bonding wire, electrically connecting the second electrical contact region with the integrated circuit; and
a substantially opaque first encapsulation material enclosing the at least one sensor element and the at least one optoelectronic component in lateral direction in such a way that at least one surface of the at least one sensor element and of the at least one optoelectronic component opposite the lead frame remains uncovered by the substantially opaque first encapsulation material.

26. The sensor device according to claim 25,
wherein a cavity or window is formed in the substantially opaque first encapsulation material above the at least one sensor element.

27. The sensor device according to claim 26,
wherein the window or cavity is filled with an at least partially transparent material.

28. The sensor device according to claim 25,
wherein the substantially opaque first encapsulation material is substantially flush with a surface of the at least one optoelectronic component opposite the lead frame.

29. The sensor device according to claim 25,
wherein at least a first electrical contact of the at least one optoelectronic component is electrically connected to the integrated circuit by means of a planar interconnect.

30. The sensor device according to claim 29,
wherein at least a second electrical contact of the at least one optoelectronic component is electrically connected to the integrated circuit by means of a bonding wire.

31. The sensor device according to claim 25,
wherein the at least one optoelectronic component is in the form of a flip chip.
